(19) United States
(12) Patent Application Publication
(10) Pub. No.: US 2025/0211198 A1
(43) Pub. Date: Jun. 26, 2025

(54) SENSOR DEVICE, INCLUDING A SURFACE ACCOUSTIC WAVE RESONATOR

(71) Applicant: WIKA Alexander Wiegand SE & Co. KG, Klingenberg/Main (DE)

(72) Inventor: Fabian PFEIFER, Elsenfeld (DE)

(73) Assignee: WIKA Alexander Wiegand SE & Co. KG, Klingenberg/Main (DE)

(21) Appl. No.: 18/987,870

(22) Filed: Dec. 19, 2024

(30) Foreign Application Priority Data
Dec. 20, 2023 (DE) 10 2023 135 982.7
Dec. 20, 2023 (DE) 10 2023 136 018.3
Feb. 13, 2024 (DE) 10 2024 000 457.2

(51) Int. Cl. H03H 9/02; H03H 9/25

(52) U.S. Cl. CPC H03H 9/02897; H03H 9/25

(57) ABSTRACT

A sensor device, which comprises a metallic carrier substrate and a surface acoustic wave resonator having a chip body. A resonator structure is embedded into or deposited onto an upper side of the chip body. The surface acoustic wave resonator is fastened to the carrier substrate with the aid of a glass layer.

This nonprovisional application claims priority under 35 U.S.C. § 119(a) to German Patent Application No. 10 2023 135 982.7, which was filed in Germany on Dec. 20, 2023, and German Patent Application No. 10 2023 136 018.3, which was filed in Germany on Dec. 20, 2023, and German Patent Application No. 10 2024 000 457.2, which was filed in Germany on Feb. 13, 2024, which are all herein incorporated by reference.

### BACKGROUND OF THE INVENTION

### Field of the Invention

The invention relates to a sensor device, including a passive surface acoustic wave resonator (hereinafter referred to by the abbreviation SAW resonator), which is configured, in particular, to measure mechanical stresses or to measure strain on a deformation body.

### Description of the Background Art

Passive surface acoustic wave sensors (SAW resonators) are generally used for the wireless monitoring of physical conditions, in particular in harsh environments. However, the limits to use for measuring strain generally arise from the design of the functional intermediate layer, which connects the SAW resonator to a surface of the deformation body.

In applications for mechanical strain measurement, such as when measuring torque or force, the SAW resonators are generally glued to a surface of the deformation body with the aid of intermediate layers or mounted directly on the deformation body. The surface of the deformation body is also referred to below as a carrier substrate, while an intermediate layer which may be present is referred to as a SAW resonator substrate, SAW wafer substrate, or as a chip body.

The direct integration of SAW resonators on the surface of a metallic deformation body imposes strict requirements on the deposition of the piezoelectric layer. Compared to manufacturing on conventional SAW wafer substrates, these structural elements have significantly lower quality factors and poorer signal properties, while the production complexity of each sensor is also much higher. In addition, the piezoelectric layer is susceptible to cracks under high loads.

Similarly to mounting strain sensors based on polymer film, the proven adhesive bonding is also used for mounting SAW resonators on carrier substrates. The use of high-performance adhesives demonstrates the ability of this bonding technology to achieve high strain transfer ratios. Compared to elastic strain sensors based on polymer films, the rigidities of piezoelectric SAW resonators are significantly higher. Despite optimized designs of the adhesive bond, this results in time- and temperature-dependent effects. In the area of the glass transition temperature of the adhesive, in particular, significant changes in the strain transfer properties occur, including the irreversible detuning of the SAW resonator.

Approaches for melting an applied rear metallization of SAW sensors with metallic carrier substrates, using highly reactive nanofilms, result in high locally introduced thermal stresses, due to temperature gradients within the SAW resonator. The high temperatures necessary for melting the metallic boundary surfaces also result in damage to the crystal structure of the SAW resonator substrate.

An alternative joining method, hereinafter referred to as the bonding method, is therefore needed to fasten SAW resonators to metallic deformation bodies for expanded operating temperature ranges and high strain transfer rates under harsh environmental conditions.

### SUMMARY OF THE INVENTION

It is therefore an object of the invention to specify a new kind of sensor device, including a surface acoustic wave resonator.

According to an example of the present invention, a sensor device comprises a metallic carrier substrate and a surface acoustic wave resonator.

The metallic carrier substrate is, for example, part of a deformation body, which is subjected to mechanical stresses or forces and is deformed as a result of these mechanical stresses and forces. The deformation of the deformation body is to be made detectable with the aid of the surface acoustic wave resonator, which may also be referred to as a sensor element. In particular, the carrier substrate, i.e., the deformation body, at least also in sections, is formed from a high-grade steel. As a result, the deformation body may be used in a multiplicity of applications. For example, the deformation body may be designed as a capsule pressure gauge or as a force transducer.

The surface acoustic wave resonator comprises a chip body. A resonator structure can furthermore be embedded into an upper side of the chip body or deposited onto the upper side.

For example, the resonator structure may comprise a so-called one-port resonator, which includes a transceiving interdigital converter between two almost completely reflecting electrode grids, which form a resonance chamber. The emerging and reflected waves between the interdigital converter and the reflector grids interfere to form a standing wave. The wavefield thus generated has an extremely narrow band as a result of the multiple reflection.

The surface acoustic wave resonator can be fastened to the carrier substrate with the aid of a glass layer. This may be, for example, a lead-free glass layer, since lead-containing glasses are increasingly to be avoided, due to a heightened normative environmental awareness on the part of the market. In the context of using glass as a bond, the glass may also be referred to as a glass solder or solder glass. Glass layers may be produced, for example, by a deposition of a glass frit or glass paste to the carrier substrate and a subsequent melting of the glass frit or paste.

By using a glass for bonding the surface acoustic wave resonator to the carrier substrate, instead of using an adhesive as known from the prior art, the sensor device may have significantly more versatile uses under significantly more challenging environmental conditions. Glass solders are thus generally insensitive to moisture and, if the ambient temperature is below the glass transition temperature, have approximately temperature-independent material properties over a broad temperature range. This applies, for example, to their dynamic modulus as well as their coefficient of thermal expansion (CTE). Glasses furthermore demonstrate a significantly weaker viscoelastic behavior, compared to adhesives. A consistently high transfer of mechanical stresses from the carrier substrate to the surface acoustic wave resonator may thus be achieved over a broader temperature range independently of the stress duration, and thus an improved measuring accuracy.

In an example of the sensor device, the glass layer can be arranged, at least in sections, between an underside of the chip body opposite the upper side and the carrier substrate. The glass layer has an outer margin, which frames marginal surfaces, i.e. edge sides, formed between the upper side and the underside of the chip body. The outer margin of the glass layer encloses a defined surface section of the carrier substrate, which is covered by the glass layer; the glass layer adheres, in particular, to the entire surface area of this surface section on the carrier substrate, and no gas or air inclusions are present. The marginal region of the chip body is surrounded by the outer margin of the glass layer, which means that the chip body is fastened to the carrier substrate by the glass solder along its entire base surface defined by the foundation shape and does not protrude past the outer margin of the glass layer at any point, i.e., even not at any corner. Instead, the outer margin of the glass layer fully protrudes over the foundation shape of the chip body, which means that there is no non-disappearing distance exists between the outer margin and the chip body. In particular, no gas or air inclusions exist between the glass layer and the chip body. Due to this example, a particularly uniform transfer of mechanical stresses from the carrier substrate to the surface acoustic wave resonator may be achieved. In addition, the bonding of the surface acoustic wave resonator is particularly stable in this example with respect to its adhesion to the carrier substrate. The fact that the glass layer in this design is arranged between the underside of the chip body and the carrier substrate “at least in sections” may mean that a section of the glass layer is situated in this exact location. However, other sections of the glass layer, in particular those which project laterally over the chip body in a top view, do indeed also extend in regions above the underside. The glass layer may, in particular, partially or even completely cover the marginal surface of chip body formed between the upper side and the underside of the chip body, so that only the upper side of the chip body projects completely out of the glass layer or is at least not covered by the glass layer, as explained in greater detail below.

In an example, the chip body may have a foundation shape, and the glass layer may have a base shape which is symmetrical to the foundation shape of the chip body. However, the base shape can be scaled to be larger than the foundation shape, so that the ship body may be reliably framed by the glass layer, as explained in the above. The chip body can be positioned symmetrically and in a centered manner within the glass layer. In particular, the centers of gravity and axes of symmetry of the base shape and the foundation shape can be situated one above the other, and the base shape protrudes essentially equidistantly over the foundation shape on all sides. This means that a distance between an outer margin of the base shape and an outer margin of the foundation shape is at least essentially constant.

In an example of the sensor device, the chip body, i.e., its foundation shape, and the base shape of the glass layer can be provided with a polygonal design. In particular, the chip body has a height and a defined foundation shape perpendicular to its height. The foundation shape can be defined, for example, by an even number of at least four corners as well as by a corresponding number of straight side edges formed in each case between two adjacent corners. The foundation shape also has, for example, at least two axes of symmetry. The foundation shape of the chip body may thus correspond, for example, to a rectangle or a square. Deviating therefrom, the foundation shape and the base shape may each have a different number of corners. It is also possible that the foundation shape and the base shape are not angular, but are, for example, round or oval or designed as a free form. In the case of an angular design, a side edge is formed in each case between two adjacent corners, a number of the corners of the base shape matching that of the foundation shape. Due to the surface tension and viscosity of typical glass solders, in particular in the case of low-melting solder glasses (which may be particularly advantageous in this application, as explained below in the context of an example), no arbitrarily sharp corners or completely straight edge regions may be implemented. Instead, the outer margin of the glass layer runs continuously without exception, without abrupt changes or kinks. Within the meaning of this example, “corners” of the base shape can therefore correspond, for example, to rounded areas having a more or less small radius, and the side edges of the base shape may deviate from a straight course, have rounded areas, protrusions, and indentations, without deviating from the teaching of this example. Side and length ratios of the base shape equal those of the foundation shape with the same axes of symmetry, at least within the scope of the technically achievable accuracy when applying a glass frit or glass paste as well as during the melting of the glass frit or paste.

In an example of the sensor device, the outer margin of the glass layer can have an outwardly oriented protrusion at each of the corners of the base shape. It may be advantageously achieved thereby that a plateau region forms in the middle of the glass layer, which does not descend too sharply even in the regions of the corners of the base shape. In this plateau region, the chip body may be reliably bonded over its entire base surface and its side surfaces, in particular if the chip body is to be placed in a partially sunken manner in the glass layer.

In an example of the sensor device, the outer margin of the glass layer may be spaced apart from a nearest side edge of the chip body, at least in sections, by no more than a first length, at least at a point between two consecutive corners of the base shape. At at least one of the protrusions, the outer margin may likewise be spaced apart from a nearest corner of the chip body at least by a second length, at least in sections, the second length being at least 10% greater than the first length. In particular, the second length is at least 50% greater, in particular at least 100% greater, than the first length. The fact that the spacings mentioned above are to be present at “at least one point between consecutive corners of the base shape” or at “at least one of the protrusions” can mean that the same distances do not have to be maintained at all points between all possible pairs of two consecutive corners of the base shape or not at all protrusions—while maintaining the symmetries established above.

In an example of the sensor device, the outer margin can have, however, a point between each pair of two adjacent protrusions which is spaced apart from the nearest side edge of the chip body by no more than the first length, at least in sections. The outer margin at each of the protrusions in this example is likewise spaced apart from the nearest corner of the chip body by at least the second length, at least in sections. In the context of this example as well as in all following paragraphs having the same context, “at least in sections” can mean that the particular feature—i.e., the particular minimum or maximum distance—is met at at least one point along the outer margin. In particular, the particular features are not upheld at only one point, but rather along a cohesive segment of the outer margin. Due to the maximum and minimum distances indicated in this example, the features and advantages of the example mentioned above may be implemented particularly efficiently. By maintaining a maximum distance of no more than the first length, at least in sections, in regions between two protrusions, the total size of the surface section covered by the glass layer may be limited and thus also the total quantity of the glass frit or glass solder needed for manufacturing this surface covering. At the same time, maintaining a minimum distance of at least the second length, at least in sections, at the protrusions ensures that a plateau region forms in the middle of the glass layer, within which the chip body may be reliably, stably, and precisely placed.

As an example, the base shape of the glass layer may furthermore completely project laterally over the foundation shape or project past the foundation shape by 3 to 7 times, in particular by 4 to 6 times, in particular by exactly 5 times a height of the chip body. This means that the outer margin is always situated remotely from the nearest corner or side edge of the chip body by this distance; due to this distance, which is indicated in multiples of the height of the chip body, a minimum distance is thus defined between the outer margin and the chip body. In this parameter range, a flux of force or a transfer of mechanical stresses from the carrier substrates to the surface acoustic wave resonator may be implemented particularly effectively and with the optimal amount of material used. In connection with the directly preceding example described, it may be provided that the first length corresponds exactly to the multiple of the height of the chip body mentioned in this example or is selected to be only slightly greater, for example, 5 to 10 percent greater. The advantages of both examples may be combined thereby.

Furthermore, it may be provided, regardless of a specific base shape of the glass layer, that the outer margin can be spaced apart from the chip body in a region along at least one side edge thereof by no more than a first length, at least in sections, and is spaced apart from the chip body in a region at at least one corner thereof by a second length, at least in sections, the second length being at least 10% greater, in particular at least 50% greater, in particular at least 100% greater than the first length. The first length and the second length from this example may be understood to correspond to the first length and second length, respectively, described in an example above. Statements relating to concepts such as “at least one” and “at least in sections” from preceding paragraphs may be applied analogously to this example. Likewise, the same advantages explained in the preceding paragraph with regard to the first and second lengths may be achieved with the aid of features from this example. In contrast to the preceding example, this example is not limited only to the fact that the glass layer must have a recognizable base shape with protrusions.

The chip body may also have a foundation shape, which can be formed by the side edges as well as by an even number of at least four corners, the foundation shape having, for example, at least two axes of symmetry. However, deviating angular designs of the foundation shape are also possible here.

It may furthermore be provided that, at any point, the outer margin can be spaced apart from a nearest side edge or corner of the chip body at least by 3 to 7 times, in particular 4 to 6 times, in particular 5 times the height of the chip body. A minimum distance between the outer margin and the chip body is defined by this example. In this parameter range, a flux of force or a transfer of mechanical stresses from the carrier substrates to the surface acoustic wave resonator may be implemented particularly effectively and with the optimal amount of material used. In connection with the measures of this refinement mentioned above, it may be provided that the first length corresponds exactly to the multiple of the height of the chip body mentioned in this example or is selected to be only slightly greater, for example, 5 to 10 percent greater. The advantages of both exemplary refinements may be combined thereby.

A surface of the glass layer can abut the upper side of the chip body at least in an essentially flush manner at least along a marginal section of the chip body. The marginal section may comprise marginal surfaces of the chip body, at least in sections, in particular, one or multiple side edges of the chip body and/or one or multiple corners of the chip body. In this context, “essentially in a flush manner” can mean that the glass layer does not cover any part of the upper side of the chip body, i.e., it does not extend beyond a side edge onto the upper side of the chip body. This also means that no abrupt step remains between the surface of the glass layer and the upper side of the chip body. The surface of the glass layer thus ends exactly at the marginal section bordering the upper side of the chip body. In particular, the surface of the glass layer transitions continuously into the upper side of the chip body at the marginal section. An abrupt change in gradient, i.e., a kink in the course during the transition from the glass layer to the upper side can also be understood as in essentially a flush manner in the context of this example. Due to this design, a particularly effective flux of force or a particularly effective transfer of mechanical stresses between the carrier substrate and the surface acoustic wave resonator may be achieved. In particular, forces or mechanical stresses may be transferred directly into the uppermost layer of the chip body, in which the surface acoustic waves move within the resonator structure. At the same time, an impairment of the function of the surface acoustic wave resonator is effectively prevented by the essentially flush termination. It is apparent, namely, that surface acoustic waves which are excited in the chip body on the upper side thereof are greatly disrupted when even small amounts of glass extend over a marginal section onto the upper side of the chip body. In addition, glass layer parts of this type which extend in places over the upper side of the chip body could result in warping on the upper side during changes in temperature, which would also greatly disrupt the wavefield or the measurement properties of the surface acoustic wave resonator. Due to the flush connection of the glass layer to the marginal section, it may also be achieved that microcracks and microscopic edge spalling or chipping on the chip body, which may basically occur due to the process during the manufacturing of the chip body, are repaired by wetting with the solder glass, as a result of the geometric features of this design. This means that the glass may flow into and fill in these cracks and chipping during the bonding of the chip body on the carrier substrate. The measurement properties of the surface acoustic wave resonator may be improved thereby, and it sensitivity to environmental influences may be reduced, and the mechanical stability of the sensor device as well as its reliability under long-term and alternating load may be improved Correspondingly, it may be advantageously provided in one example that the surface of the glass layer abuts the chip body in an essentially flush manner along all side edges and corners thereof, so that the surface of the glass layer does not abut the upper side of the chip body in flush manner at any marginal section thereof.

The corners of the foundation shape of the chip body can be provided with a rounded design. A corner shape of this type may be achieved, for example, by etching methods. Due to this example, a bonding of the chip body to the glass layer may be improved. In particular, a fully circumferential, at least essentially flush connection of the surface of the glass layer to the upper side of the chip body may be made easier in this example, as proposed in the preceding example.

The surface of the glass layer may first ascend initially to a highest point which is higher than the upper side of the chip body, at least along a marginal section of the chip body in its course away therefrom up to its outer margin. Depending on the surface tension, viscosity, and angle at which the surface of the glass layer abuts the marginal section of the chip body, the surface may undergo a change in its doming from initially concave to convex; however, the surface may also run in a convex manner over its entire course from the marginal section to the outer margin. After reaching the highest point, it descends continuously toward the outer margin, in any case without forming a macroscopic section having a concave shape. The doming thus remains convex over the further course, and the curvature may, however, decrease in the direction of the margin. In a cross-section which runs, for example, perpendicularly to the surface of the carrier substrate and to the marginal section, the surface of the glass layer thus follows a curve which initially has no more than one point of inflection, followed by a peak, and then no further points of inflection, saddle points, or peaks, in a direction away from the marginal section of the chip body and toward the outer margin of the glass layer. The aforementioned should not prevent the glass layer from possibly forming a convex end section directly at the outer margin on the microscopic level, depending on its surface tension, viscosity, and possible microstructures of the surface of the carrier substrate. The marginal section at which the surface of the glass layer subsequently has the profile defined according to this example may comprise one or multiple side edges of the chip body and/or one or multiple corners of the chip body, at least in sections. Due to this example, it may be advantageously achieved that the effective cross-sectional surface of the part of the glass layer which frames the chip body is enlarged, and mechanical stress peaks may be reduced or deflected thereby. The stability of the sensor device may be improved thereby, and greater deformations may be transferred from the carrier substrate to the surface acoustic wave resonator without damaging the glass layer. This means that the reliable maximum nominal strain is increased. Due to the formation of the course having a highest point which is higher than the upper side of the chip body, the surface acoustic wave resonator may be protected to some extent against contact with other bodies, which is explained in greater detail below, in particular, in the context of a subsequent refinement.

Due to the advantages mentioned above, it may be provided that the marginal section, along which the surface of the glass layer can take the described course away therefrom and toward its outer margin, comprises all side edges and corners of the chip body. This means that the glass layer forms a ring wall-like collar, which surrounds the entire circumference of the surface acoustic wave resonator. The advantages mentioned above may be effectively used thereby all around the circumference of the chip body.

The highest point of the course of the surface of the glass layer described in this example may be, for example, higher than the upper side of the chip body by 10% to 75%, in particular by 25% to 50%, of the height of the chip body. The advantageous effects of this example may be used thereby particularly effectively and with an optimized amount of material used. The limitation of the height of the highest point according to the limits given herein also prevents a tensile rigidity of the sensor device to be increased too much and thereby reduce a sensitivity.

The sensor device may also comprise a cover panel and a holding frame. The holding frame surrounds the entire surface section covered by the glass layer and connects the cover panel to the carrier substrate. This connection is, in particular, hermetically tight. Surface acoustic wave resonators including cover panels for protection against impairment—in particular, against dust, liquids, and other mechanical environmental influences—are known from the prior art. Up to now, however, it has been possible for a surface acoustic wave resonator to become damaged during the mounting of the cover panel and holding frame if one of the aforementioned parts falls onto the upper side of the chip body or knocks against it. Faults of this type may be avoided due to the upwardly directed doming of the glass layer, whose highest point is higher than the upper side of the chip body, since the glass layer then captures the glass panel or the frame before it is able to strike the sensitive surface of the surface acoustic wave resonator or the chip body. This protective effect may correspondingly take place particularly effectively if the glass layer forms a wall-shaped collar which completely surrounds the chip body, as illustrated in one of the preceding refinements.

The holding frame can be formed by an additional glass solder ring or an additional frame made from glass solder. The holding frame may thus be manufactured using the same or similar process steps and parameters as the connection between the chip body and the carrier substrate, by which means the manufacturing of the sensor device may be made efficient. In particular, a glass solder may be used for the holding frame which has a lower melting temperature than the glass solder used for forming the glass layer. As a result, the holding frame may be manufactured after the glass layer without having to increase a process temperature to the extent that the glass layer itself melts again.

The term “marginal section” may be used, on the one hand, to designate sections at which the surface of the glass layer abuts the upper side of the chip body at least in an essentially flush manner; on the other hand, the same term can also be used for sections from which the surface of the glass layer initially ascends in its course toward its outer margin up to its highest point, which is higher than the upper side of the chip body, and then descends steadily to the outer margin without forming a macroscopic, concavely shaped section. To avoid ambiguities, let it be said explicitly at this point that these marginal sections in examples of the sensor device may be the same ones—i.e., a flush connection and corresponding course to a highest point on the same marginal section combined—as well as different marginal sections—i.e., a flush connection only at sections from which the surface of the glass layer does not ascend to a highest point up to its outer margin. Likewise, the marginal sections having the one feature and marginal sections having the other feature may also only partially overlap. The two versions may also be used in a fully circumferential manner at the same time, that is, provided without interruption along all side edges and corners of the chip body.

The chip body can be formed from an anisotropic material, which, in a first direction, has a first coefficient of thermal expansion and a first strain sensitivity and, in a second direction, which is orthogonal to the first direction, has a second coefficient of thermal expansion and a second strain sensitivity which differ from the first coefficient of thermal expansion and the first strain sensitivity in each case. The chip body can be shaped and cut in such a way that the first and second directions are situated in a plane in parallel to the upper side of the chip body. The second coefficient of thermal expansion is lower than the first coefficient of thermal expansion. A coefficient of thermal expansion of the carrier substrate is also selected to be lower than the first coefficient of thermal expansion and simultaneously higher than the second coefficient of thermal expansion. This makes it possible to achieve that mismatches of the coefficients of thermal expansion between the chip body and carrier substrate are present, which, however, each have different signs along the first and second directions. This results, for example, in that the chip body undergoes a relative compression in a first direction during a rise in temperature (i.e., a negative strain or reduction in a stretch), while it simultaneously undergoes a relative stretch in the second direction (i.e., a positive strain or reduction of a compression). Since the surface acoustic wave resonator is fastened to the carrier substrate with the aid of a glass solder, it therefore undergoes a stretch, i.e. positive strain, in the first direction and a compression, i.e. negative strain, in the second direction during the course of the bonding process while the glass solder cools and solidifies. At the end of the bonding process, the chip body is therefore prestressed due to the predetermined mismatches of the coefficients of thermal expansion. In this example, the material of the chip body is now selected and oriented in such a way that the first strain sensitivity is negative and the second strain sensitivity is positive. In this context, a negative strain sensitivity means that the resonance frequency of the surface acoustic wave resonator decreases as the positive strain, i.e. stretch, increases. Correspondingly, a positive strain sensitivity means that the resonance frequency increases as the positive strain, i.e. stretch, increases. In the case of surface acoustic wave resonators, the strain sensitivity may be expressed, in particular, as the rate of change of the resonance frequency, i.e., ∂Δƒ/∂ε, Δƒ being the difference between the instantaneous resonance frequency and an output frequency, and ε being the strain. The prestress of the chip body in both directions thus results in each case in a reduction of the resonance frequency. However, the material ƒ the chip body is to simultaneously have a temperature response, i.e., a temperature dependency of the resonance frequency which results in an increase in the resonance frequency during the cooling process. Correspondingly, the influence of mismatched coefficients of thermal expansion in both directions counteracts the temperature response of the chip body in each case and thus effectively reduces the thermal cross-sensitivity of the surface acoustic wave resonator. Correspondingly, a higher measuring accuracy over broad temperature ranges may be achieved with the aid of a sensor device according to this example if the resonator structure and thus the wavefield direction (also referred to as the propagation direction of the wavefield) runs in parallel to the first or the second direction.

The effectiveness of this prestress and reduction of the thermal cross-sensitivity may be used over a broad temperature range particularly due to the bonding according to the invention with the aid of a glass solder instead of an adhesive. Adhesives generally have greatly temperature-dependent coefficients of thermal expansion, while those of glass solders are significantly less temperature-dependent.

In a further example of the sensor device, the surface acoustic wave resonator can have a mean resonance frequencies of 434 MHz or 2.4 GHz, and the chip body has a side length of at least 1.5 mm to a maximum of 5 mm, in particular, at least 2 mm to a maximum of 3 mm. Due to the use of the aforementioned frequency, a contactless reading out of the surface acoustic wave resonator may be carried out license-free and frequently even without approval in many regions, since these frequencies are within the standardized ISM bands. Alternatively or additionally, the resonator structure has a length of at least 1 mm, in particular, at least 1.5 mm. Due to the combination of these parameters, a smaller installation size is achieved along with a sufficiently high quality of the resonator, so that the sensor device may be reliably used to carry out a measuring task.

The chip body can have a thickness of at least 20 μm to a maximum of 100 μm, in particular at least 25 μm to a maximum of 60 μm. At the same time, in a surface region directly beneath the chip body, the glass layer has a thickness of at least 10 μm to a maximum of 200 μm, in particular at least 12.5 μm to a maximum of 120 μm. Due to these dimensions, a stable bond may be achieved between the chip body and carrier substrate, and a reliable transfer of force may be achieved from the carrier substrate to the chip body with a simultaneously optimized amount of material used.

The chip body can be formed from alpha quartz, this being a Y-35° X cut, a Y-34° X cut, or a Y-33° X cut. The resonance structure can be oriented in such a way that it extends along the x direction. This material selection may be used, in particular, to implement the design mentioned above, in which certain thermal prestresses are generated in the chip body, since all requirements imposed on the chip body are met thereby, and glass solders are available which meet the necessary conditions in combination with this chip body material. In the present case, a Y-35° X-cut can be understood to be a Y cut, which, however, is rotated 35° around the X axis. A non-rotated Y cut is a cut which runs perpendicularly to the Y axis. In the notation according to ANSI/IEEE Std 176-1987, this cut may thus be indicated as YXwlt 0°/35°/0°.

The glass layer can be formed from a low-melting glass solder, in particular, from a glass solder having a melting temperature below 500° C. As a result, less high temperatures are needed to melt the glass solder, so that the sensor device may be manufactured more cost-effectively and with less expenditure of time. In addition, thermal prestresses may be reduced overall by smaller temperature differences during the manufacturing process, which, however, should not be understood to be a contradiction of the preceding example in which certain thermal prestresses are set in a targeted manner to reduce the thermal cross-sensitivity of the surface acoustic wave resonator. This design makes it possible to achieve the fact that, despite the possibly high difference between the melting temperature needed for manufacturing and the at least significantly lower operating temperature, due to thermal mismatches and residual stresses, no high mechanical stresses of this type are produced in the surface acoustic wave resonator, which could result in a damage thereto—regardless of whether thermal mismatches between the material of the chip body, the glass layer, and/or the carrier substrate are intentionally or unintentionally present.

The resonator structure can be oriented in or on the upper side of the chip body in such a way that a wavefield direction of the resonator structure runs in parallel to one of the at least two axes of symmetry of the foundation shape of the chip body. In particular, at least two axes of symmetry of the chip body are perpendicular to each other, and the resonator structure is centered around the intersection point of these axes of symmetry, the wavefield direction running in parallel to one of these two axes of symmetry. This orientation makes it possible to achieve the fact that forces and deformations of the chip body act upon the resonator structure in an essentially symmetrical manner, by which means the measuring accuracy as well as the cross-sensitivity may be reduced. This design may be particularly advantageously combined with the example described in a preceding paragraph, in which certain thermal prestresses are used in a targeted manner to reduce the thermal cross-sensitivity, when axes of symmetry of the chip body as well as crystal directions having corresponding material properties are coordinated with each other. The advantages of both design may be combined with each other thereby.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 schematically shows a top view of an example of a sensor device;

FIG. 2 schematically shows a perspective representation of a surface acoustic wave resonator;

FIGS. 3A, 3B, 3C, and 3D show examples of a chip body, schematically in each case, in a top view;

FIGS. 4A, 4B, 4C, and 4D show examples of the sensor device, schematically in each case, in a top view;

FIG. 5A schematically shows a perspective view of an example of the sensor device;

FIG. 5B schematically shows a cross-sectional view of a marginal region from FIG. 5A;

FIG. 6A schematically shows a perspective view of an example of the sensor device;

FIG. 6B schematically shows a cross-sectional view of a marginal region from FIG. 6A; and

FIG. 7 schematically shows a cross-sectional view of an example of the sensor device.

### DETAILED DESCRIPTION

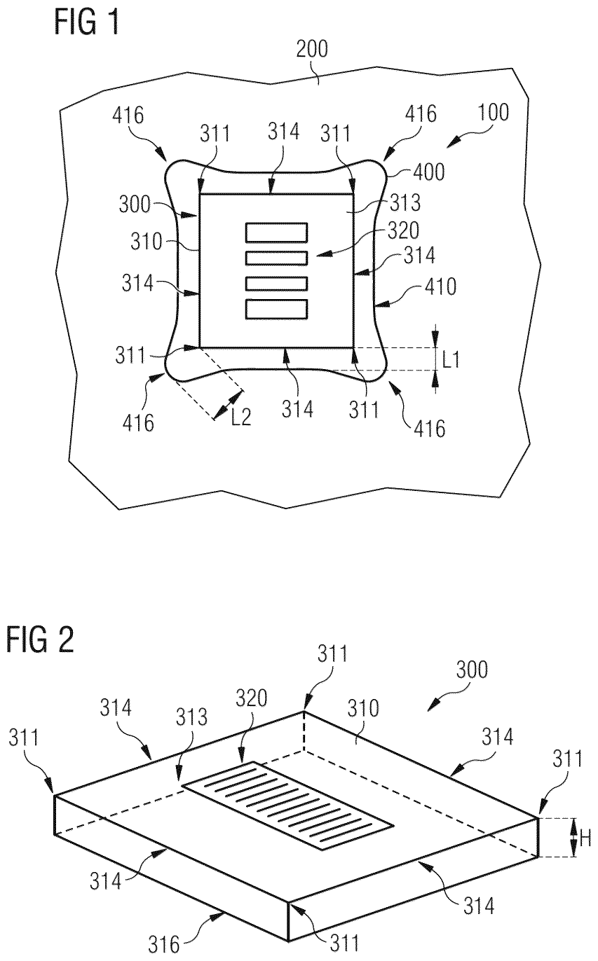

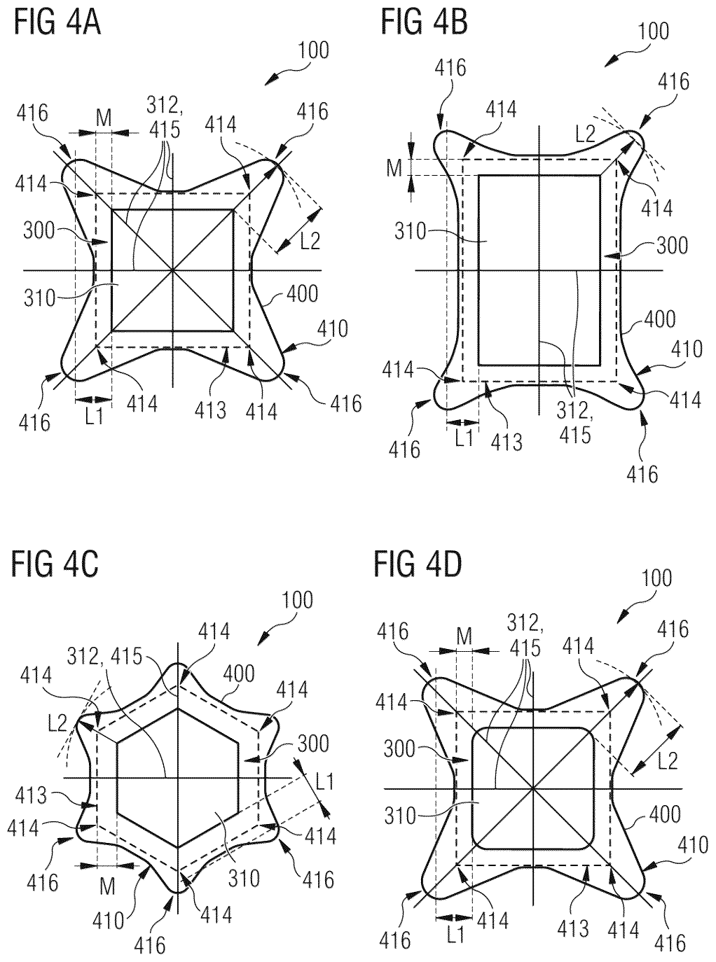

FIG. 1 shows a top view of an example of a sensor device 100. A surface acoustic wave resonator 300 is fastened to a carrier substrate 200 with the aid of a glass layer 400. Carrier substrate 200 is illustrated here only in sections and may be formed, for example, by a surface section of a deformation body, such as a capsule pressure gauge, a pressure measuring diaphragm, or a force transducer. Surface acoustic wave resonator 300 comprises a chip body 310, which in this example has a square foundation shape, which is defined by four corners 311 and four side edges 314. A resonator structure 320 is arranged in or on an upper side 313 of chip body 310, which is illustrated only schematically in a greatly simplified manner in this and the following figures. Glass layer 400 has a circumferential outer margin 410, which surrounds a surface section of carrier substrate 200, which is completely covered by glass layer 400. Glass layer 400 has a base shape 413, which is illustrated in greater detail in FIGS. 4A through 4D and which corresponds to a foundation shape 316 of chip body 310, which is also illustrated in greater detail in FIGS. 4A through 4D, but is increased in scale so that it completed overlaps or surrounds foundation shape 316 of chip body 310. Outer margin 410 also has a protrusion 416 in the region of any corner 311 of chip body 310. Chip body 310 is placed concentrically and symmetrically on or in glass layer 400. This results in the fact that, in regions along side edges 314, outer margin 410 is spaced apart from nearest side edge 314, at least in sections, by no more than a first length L1. In the region of protrusions 416, outer margin 410 is likewise spaced apart from a nearest corner 311 of chip body 310, at least in sections, by at least a second length L2. Second length L2 is at least 10% greater than first length L1.

FIG. 2 shows an example of a surface acoustic wave resonator 300 corresponding to the one in FIG. 1. Chip body 310 has a square foundation shape 316, and chip body 310 has a height H, which may also be referred to as the thickness of chip body 310.

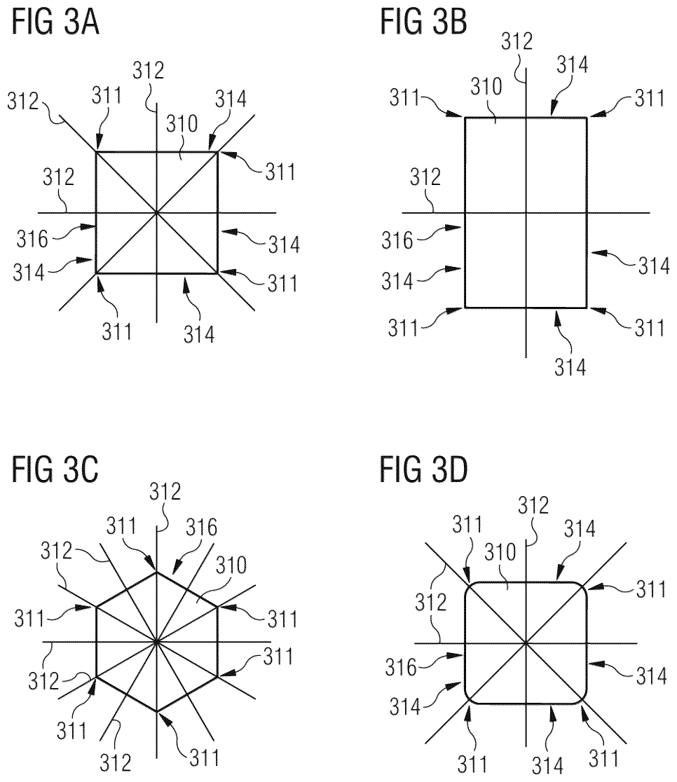

FIGS. 3A, 3B, 3C, and 3D show different examples of chip body 310, each of which differs in terms of its foundation shape 316. Axes of symmetry 312 of the different foundation shapes 316 are also drawn. A representation of resonator structure 320 is omitted in these illustrations, although it is oriented in each case in such a way that a wavefield direction of resonator structure 320 is oriented in parallel to one of axes of symmetry 312, and resonator structure 320 is centered in each case in relation to the intersection point of axes of symmetry 312.

Chip body 310 in FIG. 3A has a square foundation shape 316 and thus resembles the designs in FIGS. 1 and 2. Chip body 310 in FIG. 3B, on the other hand, has a rectangular foundation shape 316 and therefore a smaller number of axes of symmetry 312. FIG. 3C shows a chip body 310 which has a hexagonal foundation shape 316, all side edges 314 in this example having the same length. Chip body 310 illustrated in FIG. 3D resembles the one in FIG. 3A in terms of its foundation shape 316, although corners 311 are formed in a rounded manner. Each of the different foundation shapes 316 is defined by an even number of at least four corners 311 and the same number of side edges 314 arranged between two adjacent corners 311. For the sake of clarity, the reference numerals of side edges 314 were omitted in FIG. 3C.

In FIGS. 4A, 4B, 4C, and 4D, the examples of chip body 310 from the corresponding FIGS. 3A, 3B, 3C, and 3D are illustrated in a top view as part of examples of a sensor device 100. In addition, they are each positioned in a glass layer 400. Glass layers 400 each have a base shape 413 with axes of symmetry 415 which corresponds to foundation shape 316 of chip body 310 assigned in each case in terms of form and orientation, while also being larger, so that an outer margin 410 of glass layer 400 surrounds marginal surfaces of chip body 310 running between upper side 313 and the underside of chip body 310 on all sides. Chip bodies 310 are each placed concentrically and symmetrically within glass layers 400, so that outer margin 410 of glass layer 400 is spaced apart from chip body 310 circumferentially in a point-symmetrical manner (within the scope of the technically feasible manufacturing accuracy). Base shape 413 projects over foundation shape 316 on all sides at least by a minimum distance M. Glass layers 400 additionally have protrusions 416 in the region of all corners 311 of particular foundation shape 316—and thus in the region of all corners 414 of the base shape. Outer margin 410 is spaced apart from chip body 310 by no more than a distance L1, at least in sections, along side edges 314 of chip body 310 (not provided with reference numerals in FIGS. 4A, 4B, 4C, and 4D for the sake of clarity). In the region of protrusions 416, outer margin 410 is spaced apart from particular nearest corner 311 by at least a second length L2 (not provided with reference numerals in FIGS. 4A, 4B, 4C, and 4D for the sake of clarity), again at least in sections.

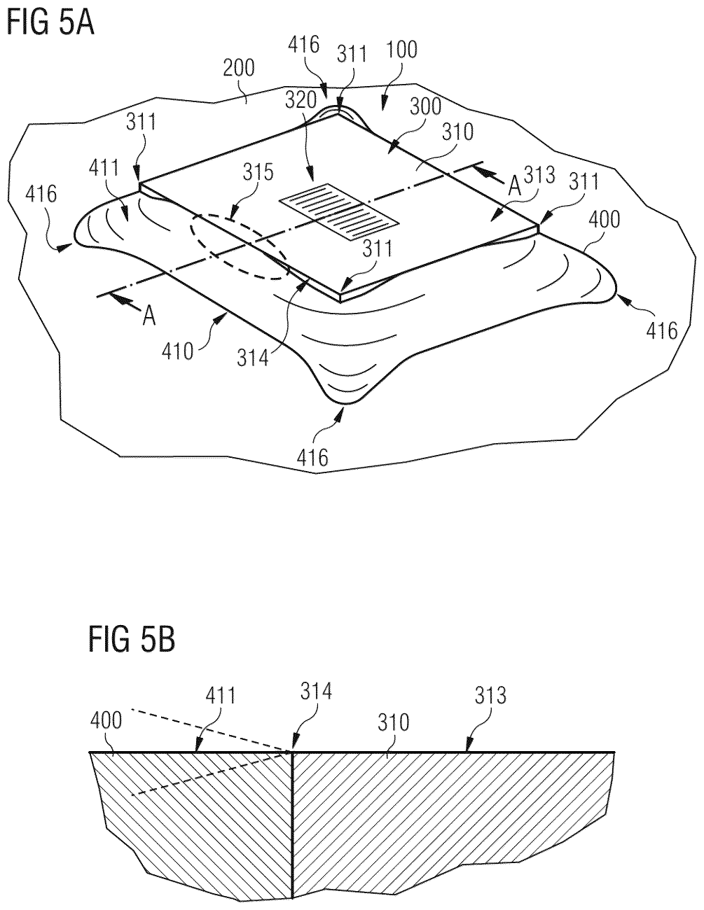

FIG. 5A shows a perspective view of an example of sensor device 100. Chip body 310 is placed partially sunk into glass layer 400. A surface 411 of glass layer 400 abuts upper side 313 of chip body 310 in a flush manner along a marginal section 315.

In FIG. 5B, marginal section 315 from FIG. 5A is illustrated in a cross-sectional view through plane A, as drawn in FIG. 5A. Surface 411 of glass layer 400 abuts upper side 313 in a flush manner, i.e., the surface of chip body 310 abuts its side edge 314. In this case, “in a flush manner” means that glass layer 400 does not extend beyond side edge 314 and thus does not cover any part of upper side 313, while at the same time no step remains between surface 411 and upper side 313, as indicated, for example, at corners 311 in FIG. 5A. In particular, surface 411 abuts glass layer 400 in a fully circumferential manner, along all corners 311 and all side edges 314, continuously flush with upper side 313. In FIG. 5B, surface 411 transitions continuously into upper side 313; however, within the meaning of this example, a slight kink in the ascent, as indicated by dashed lines in FIG. 5B, is also understood to be a flush connection.

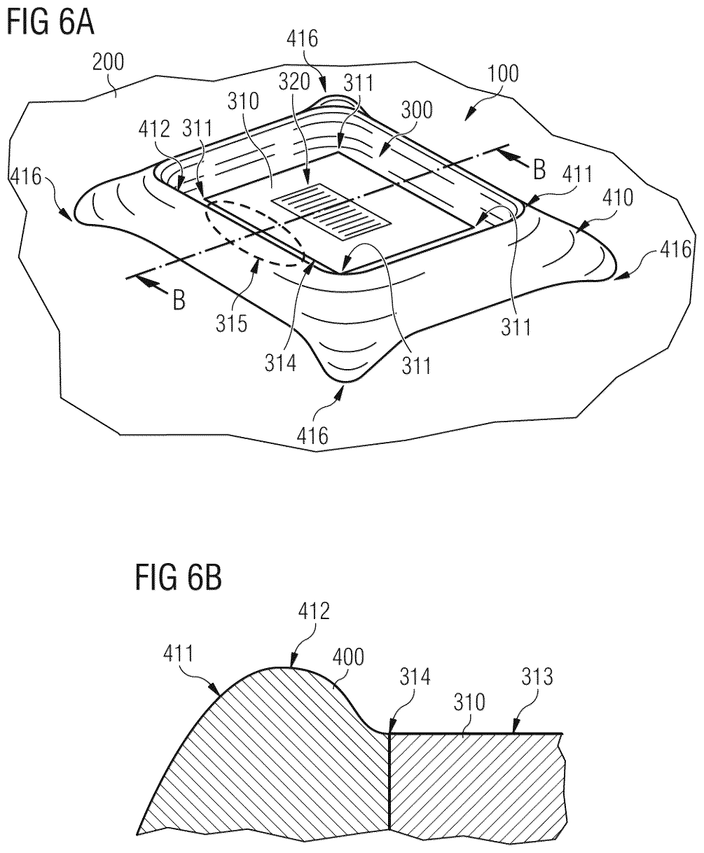

FIG. 6A shows a perspective view of a further example of sensor device 100. In its course away from chip body 310 up to its outer margin 410, surface 411 of glass layer 400 first ascends to a highest point 412, which is higher than upper side 313 of chip body 310 in the direction of its outer margin 410. It then descends steadily to outer margin 410 without forming a macroscopic section having a concave shape. The aforementioned should not prevent glass layer 400 from possibly forming a convex end section directly on outer margin 410 on the microscopic level, depending on its surface tension, viscosity, and possible microstructures of the surface of carrier substrate 200. Glass layer 400 thus forms a circumferential ring wall-like collar, which surround surface acoustic wave resonator 300 or chip body 310 in a fully circumferential manner.

In FIG. 6B, marginal section 315 from FIG. 6A is illustrated in sections in a cross-sectional view through plane B, as drawn in FIG. 6A. The course of surface 411 from side edge 314 of chip body 310 in the direction of outer margin 410 is apparent. Highest point 412 is, for example, higher than upper side 313 of chip body 310 by 10% to 75% of height H of chip body 310.

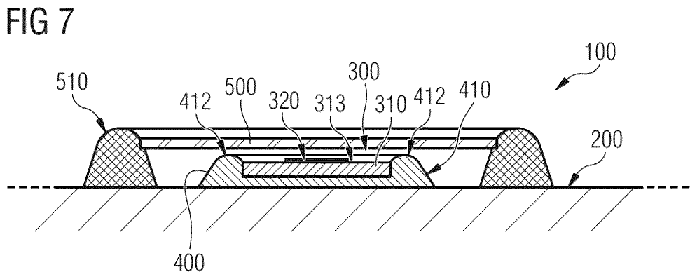

FIG. 7 shows a cross-sectional view of a further example of sensor device 100. In this example, glass layer 400 forms a circumferential collar around chip body 310, highest point 412 being higher in each case than upper side 313 of chip body 310. Surface acoustic wave resonator 300 and glass layer 400 are also surrounded by a holding frame 510, which supports a cover panel 500. Holding frame 510 is formed by a glass solder and encloses surface acoustic wave resonator 300 and glass layer 400, together with cover panel 500, in a hermetically tight manner. Since glass layer 400 forms the collar with highest point 412, sensitive upper side 313 of chip body 310 may not be damaged by cover panel 500 even if the latter is placed too deep in holding frame 510 in a sunken or tilted manner during the manufacturing process. In such cases, cover panel 500 strikes the stable collar formed by glass layer 400 instead of upper side 313 of chip body 310.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A sensor device comprising:
a metallic carrier substrate; and
a surface acoustic wave resonator that comprises a chip body and a resonator structure embedded into an upper side of the chip body or deposited onto the upper side,
wherein the surface acoustic wave resonator is fastened to the carrier substrate via a glass layer.

2. The sensor device according to claim 1, wherein the glass layer is arranged between an underside of the chip body opposite the upper side and the carrier substrate, at least in sections, and wherein an outer margin of the glass layer frames marginal surfaces formed between the upper side and the underside of the chip body.

3. The sensor device according to claim 2, wherein the chip body has a foundation shape, wherein the glass layer has a base shape substantially symmetrical to the foundation shape of the chip body; and wherein the chip body is positioned in a manner centered and substantially symmetrical to the base shape of the glass layer.

4. The sensor device according to claim 3, wherein the outer margin has an outwardly oriented protrusion at each corner of the base shape.

5. The sensor device according to claim 4, wherein the outer margin is spaced apart from a nearest side edge of the chip body by no more than a first length, at least in sections, at at least one point between two consecutive corners of the base shape, and is spaced apart from a nearest corner of the chip body at least by a second length, at least in sections, at at least one of the protrusions, and wherein the second length is greater than the first length by at least 10%, by at least 50%, or by at least 100%.

6. The sensor device according to claim 5, wherein the outer margin has a distance to the nearest side edge of the chip body that corresponds to no more than the first length at at least one point between each pair of two adjacent protrusions, at least in sections; and has, at each protrusion, a distance to the nearest corner of the chip body that corresponds at least to the second length, at least in sections.

7. The sensor device according to claim 3, wherein the base shape protrudes laterally beyond the foundation shape of the chip body on all sides by a minimum distance, wherein the minimum distance is 3 to 7 times, 4 to 6 times, or 5 times a height of the chip body.

8. The sensor device according to claim 3, wherein the foundation shape has an even number of at least four corners and at least two axes of symmetry, and wherein the base shape has a corresponding number of corners and axes of symmetry.

9. The sensor device according to claim 2, wherein the outer margin, in a region along at least one side edge of the chip body, is spaced apart therefrom by no more than a first length, at least in sections; and in a region at at least one corner of the chip body, the outer margin is spaced apart therefrom by at least a second length, at least in sections, wherein the second length is at least 10% greater, at least 50% greater, or at least 100% greater than the first length.

10. The sensor device according to claim 9, wherein the outer margin in a respective region along at least any side edge of the chip body, is spaced apart therefrom by no more than the first length, at least in sections, and wherein, in a particular region at any corner of the chip body, is spaced apart therefrom by no more than the second length, at least in sections.

11. The sensor device according to claim 9, wherein, at any point, the outer margin is spaced laterally apart from the nearest side edge or corner of the chip body by a minimum distance, the minimum distance being 3 to 7 times, 4 to 6 times, or 5 times a height of the chip body.

12. The sensor device according to claim 9, wherein the chip body has a foundation shape, which is formed by the side edges as well as by an even number of at least four corners, and wherein the foundation shape has at least two axes of symmetry.

13. The sensor device according to claim 1, wherein a surface of the glass layer abuts the upper side in an essentially flush manner at least along a marginal section of the chip body.

14. The sensor device according to claim 13, wherein the marginal section comprises all marginal surfaces of the chip body or all side edges and all corners of the chip body.

15. The sensor device according to claim 1, wherein the surface of the glass layer first ascents to a highest point, which is higher than the upper side of the chip body, at least along a marginal section of the chip body in its course away therefrom in a direction of its outer margin, and then descends steadily to the outer margin without forming a macroscopic section having a concave shape.

16. The sensor device according to claim 15, wherein the highest point is higher than the upper side of the chip body by 10% to 75% or by 25% to 50% of a height of the chip body.

17. The sensor device according to claim 15, wherein the marginal section comprises all marginal surfaces of the chip body or all side edges and all corners of the chip body.

18. The sensor device according to claim 2, further comprising a cover panel and a holding frame, wherein the holding frame surrounds the outer margin and connects the cover panel to the carrier substrate.

19. The sensor device according to claim 18, wherein the holding frame is formed from a glass solder, wherein the holding frame is formed from a different glass solder than the glass layer, and wherein this different glass solder has a lower melting temperature than the glass solder from which the glass layer is formed.

20. The sensor device according to claim 1, wherein the chip body is formed from an anisotropic material, which has a first coefficient of thermal expansion and a first strain sensitivity in a first direction, and has a second coefficient of thermal expansion and a second strain sensitivity in a second direction, which is orthogonal to the first direction, wherein the second coefficient of thermal expansion is lower than the first coefficient of thermal expansion; wherein a coefficient of thermal expansion of the carrier substrate and/or a coefficient of thermal expansion of the glass layer is lower than the first coefficient of thermal expansion and simultaneously higher than the second coefficient of thermal expansion, wherein the first strain sensitivity is negative and the second strain sensitivity is positive, wherein the chip body is formed in such a way that the first and the second directions are in a plane substantially in parallel to the upper side of the chip body, and wherein the resonator structure runs substantially in parallel to the first direction or substantially in parallel to the second direction.

21. The sensor device according to claim 1, wherein the surface acoustic wave resonator has a mean resonance frequency of 434 MHz or 2.4 GHz, wherein the chip body has a side length of at least 1.5 mm to a maximum of 5 mm or at least 2 mm to a maximum of 3 mm, and/or wherein the resonator structure has a length of at least 1 mm, or at least 1.5 mm.

22. The sensor device according to claim 1, wherein the chip body has a thickness of at least 20 μm to a maximum of 100 μm, or at least 25 μm to a maximum of 60 μm, and wherein the glass layer has a thickness of at least 10 μm to a maximum of 200 μm or at least 12.5 μm to a maximum of 120 μm in a surface region directly beneath the chip body.

23. The sensor device according to claim 1, wherein the chip body is formed from alpha quartz, this being a Y-35° X cut, a Y-34° X cut, or a Y-33° X cut, and wherein the resonator structure extends along the x direction.

24. The sensor device according to claim 1, wherein the glass layer is formed from a low-melting glass solder or from a glass solder having a melting temperature below 500° C.

25. The sensor device according to claim 1, wherein the corners of the chip body are provided with a rounded design.
